(19) United States
(12) Patent Application Publication
(10) Pub. No.: US 2014/0008726 A1
(43) Pub. Date: Jan. 9, 2014

(54) SEMICONDUCTOR STRUCTURE AND METHOD OF FABRICATING THE SAME

(71) Applicants: Yu-Jen HSIAO, Tainan (TW); Ting-Jen HSUEH, Tainan (TW); Jia-Min SHIEH, Hsinchu (TW); Yu-Ming YEH, Tainan (TW); Chee-Wee LIU, Taipei (TW); Bau-Tong DAI, Hsinchu (TW); Fu-Liang YANG, Hsinchu (TW)

(72) Inventors: Yu-Jen HSIAO, Tainan (TW); Ting-Jen HSUEH, Tainan (TW); Jia-Min SHIEH, Hsinchu (TW); Yu-Ming YEH, Tainan (TW); Chee-Wee LIU, Taipei (TW); Bau-Tong DAI, Hsinchu (TW); Fu-Liang YANG, Hsinchu (TW)

(73) Assignee: National Applied Research Laboratories

(21) Appl. No.: 13/541,751

(22) Filed: Jul. 4, 2012

(51) Int. Cl. H01L 29/772; H01L 21/336

(52) U.S. Cl. 257/347; 438/151; 257/E21.409; 257/E29.242

(57) ABSTRACT

A semiconductor structure fabricating method includes the following steps. Firstly, a silicon substrate is provided. The silicon substrate has a first surface and a second surface. In addition, a first semiconductor structure is formed on the first surface of the silicon substrate. Then, the second surface of the silicon substrate is textured as a rough surface. Then, a first electrode layer is formed on the rough surface.

### FIELD OF THE INVENTION

The present invention relates to a semiconductor structure and a method of fabricating the semiconductor structure, and particularly to a bifacial semiconductor structure and a method of fabricating the bifacial semiconductor structure.

### BACKGROUND OF THE INVENTION

According to the quantum energy levels, the copper-based compound semiconductor has higher photovoltaic conversion efficiency than silicon. Conventionally, a copper-based compound semiconductor solar cell is formed by using a sodium-containing glass substrate (e.g. a soda-lime glass substrate). For increasing the photovoltaic conversion efficiency, the glass substrate should be heated to 500° C. (or higher) to enhance diffusion of sodium elements into the copper-based compound semiconductor layer. However, if the sodium-containing glass substrate is not used, an additional layer of alkali-precursor (e.g. sodium fluoride or other sodium-containing compounds) is required to supply and diffuse the sodium elements into the copper-based compound semiconductor layer.

In the current semiconducting industry, the fabricating process of the silicon substrate is more popular because the equipment is relatively cost-effective. For reducing the fabricating cost, the copper-based compound semiconductor structure may be integrated with the silicon substrate fabricating process, or a bifacial semiconductor structure may be fabricated on a silicon substrate. However, since these fabricating processes are carried out at the temperature higher than 600° C., the metallic elements (e.g. Mo, Na or Cd) added to the copper-based compound semiconductor structure may diffuse into the silicon semiconductor structure. The metal ion contamination may deteriorate the performance of the silicon semiconductor structure. For protecting the silicon substrate from the metal ion contamination, a plurality of nitride or oxide insulating layers (e.g. a SiO2/SiNx/SiO2 layers) are firstly formed on the silicon substrate to be used as barrier layers, and then the copper-based compound semiconductor structure is formed.

FIG. 1 is a schematic cross-sectional view illustrating a conventional bifacial semiconductor structure.

As shown in FIG. 1, a silicon substrate 100 is firstly provided. The silicon substrate 100 has a first surface 110 and a second surface 120. Then, a first semiconductor structure 111 is formed on the first surface 110 of the silicon substrate 100. For example, the first semiconductor structure 111 is a functional circuit that is implemented by a complementary metal-oxide-semiconductor (CMOS). Moreover, a tungsten titanium (TiW) layer is formed on the second surface 120 of the silicon substrate 100 to be used as a first electrode layer 121. Then, a first silicon dioxide layer 122, a silicon nitride layer (SiNx) 123 and a second silicon dioxide layer 124 are sequentially formed on the first electrode layer 121. These isolating layers 122, 123 and 124 have a stack thickness of about 800 nm. Then, a molybdenum (Mo) layer is formed on the second silicon dioxide layer 124 to be used as a second electrode layer 125. Then, an alkali-precursor 126 (e.g. sodium fluoride or other sodium-containing compounds), which is indicated by the dashed line, is added to top surface of the second electrode layer 125. After a copper-based compound semiconductor structure layer 127 is produced at the temperature higher than 600° C., the bifacial semiconductor structure is fabricated. Then, the functional circuit of a second semiconductor device (e.g. a copper-based compound semiconductor solar cell) is formed on the copper-based compound semiconductor structure layer 127. It is noted that the first electrode layer 121 is used as the bottom electrode of the first semiconductor structure 111 and the second electrode layer 125 is used as the bottom electrode of the copper-based compound semiconductor structure layer 127. Moreover, the bifacial semiconductor structure has no common electrode for electrically connecting the first semiconductor structure and the second semiconductor device. Although the above bifacial semiconductor structure can be formed on the silicon substrate, the fabricating method is very complicated.

Therefore, there is a need of providing an improved bifacial semiconductor structure and an improved method of fabricating the bifacial semiconductor structure.

### SUMMARY OF THE INVENTION

An aspect of present invention provides a semiconductor structure fabricating method for fabrication of a bifacial semiconductor device. The semiconductor structure fabricating method includes the following steps. Firstly, a silicon substrate is provided. The silicon substrate has a first surface and a second surface. In addition, a first semiconductor structure is formed on the first surface of the silicon substrate. Then, the second surface of the silicon substrate is textured as a rough surface. Then, a first electrode layer is formed on the rough surface.

In an embodiment, the step of texturing the second surface of the silicon substrate as the rough surface includes sub-steps of forming a metal layer on the second surface of the silicon substrate, annealing the metal layer to form a plurality of metal nanoballs, performing a plasma etching process to texture the second surface of the silicon substrate by using the metal nanoballs as a hard mask to have the second surface of the silicon substrate texture as the rough surface, and removing the metal nanoballs after the plasma etching process is performed.

In an embodiment, the metal layer is a gold (Au) layer having 1˜30 nm thickness.

In an embodiment, the first electrode layer is formed by depositing a molybdenum (Mo) layer.

In an embodiment, the semiconductor structure fabricating method further includes a step of forming a copper-based compound semiconductor structure layer to cover the first electrode layer. In an embodiment, the step of forming the copper-based compound semiconductor structure layer includes the following sub-steps. Firstly, a crystal seed layer having about 0.2˜20 nm thickness is formed over the first electrode layer by a co-evaporation process or a sputtering process, wherein the crystal seed layer includes copper, gallium and selenide atoms. Then, the copper-based compound semiconductor structure layer is formed on the crystal seed layer by a three-stage co-evaporation process or a three-stage sputtering process, so that the first electrode layer is covered by the copper-based compound semiconductor structure layer.

In an embodiment, the copper-based compound semiconductor structure layer is produced at a temperature lower than 550° C.

In an embodiment, the semiconductor structure fabricating method further includes steps of forming a buffer layer on the copper-based compound semiconductor structure layer, forming a transparent conductive oxide layer on the buffer layer, forming a second electrode layer over the transparent conductive oxide layer, and forming an anti-reflection layer over the second electrode layer.

In an embodiment, the buffer layer is an n-type semiconductor layer.

In an embodiment, the transparent conductive oxide layer is formed by depositing an aluminum-doped zinc oxide (AZO) layer.

In an embodiment, the step of forming the second electrode layer includes sub-steps of forming an aluminum layer on the transparent conductive oxide layer, and partially removing the aluminum layer, wherein the remaining aluminum layer is acted as the second electrode layer.

In an embodiment, the anti-reflection layer is formed by depositing a magnesium fluoride (MgF₂) layer.

In an embodiment, the semiconductor structure fabricating method further includes steps of forming a first insulating layer on the first electrode layer, partially removing the first insulating layer to expose a part of the first electrode layer, forming a copper-based compound semiconductor structure layer on the exposed part of the first electrode layer and the remaining first insulating layer, partially removing the copper-based compound semiconductor structure layer to expose a part of the first electrode layer, and forming an isolation structure on the exposed part of the first electrode layer. By the isolation structure, the remaining copper-based compound semiconductor structure layer is divided into a third semiconductor structure and a fourth semiconductor structure.

In an embodiment, the first insulating layer is formed by depositing a silicon dioxide layer.

In an embodiment, the step of forming the isolation structure includes sub-steps of depositing a silicon dioxide layer to cover the remaining copper-based compound semiconductor structure layer and the exposed part of the first electrode layer, and partially removing the silicon dioxide layer to expose the remaining copper-based compound semiconductor structure layer, so that the remaining silicon dioxide layer is acted as the isolation structure.

In an embodiment, the semiconductor structure fabricating method further includes steps of forming a buffer layer on the third semiconductor structure, forming a transparent conductive oxide layer on the buffer layer, forming a third electrode layer over the transparent conductive oxide layer, forming an anti-reflection layer over the third electrode layer, forming a gate insulating layer on the fourth semiconductor structure, partially removing the gate insulating layer to expose a part of the fourth semiconductor structure, forming a source/drain metal electrode layer on the exposed part of the fourth semiconductor structure, and forming a metal gate layer on the remaining gate insulating layer.

Another aspect of present invention provides a bifacial semiconductor structure. The bifacial semiconductor structure includes a silicon substrate, a first electrode layer, and a copper-based compound semiconductor structure layer. The silicon substrate having a first surface and a rough surface, wherein a first semiconductor structure is formed on the first surface of the silicon substrate. The first electrode layer is formed on the rough surface. The copper-based compound semiconductor structure layer is formed over the first electrode layer.

In an embodiment, the bifacial semiconductor structure further includes a buffer layer, a transparent conductive oxide layer, a second electrode layer, and an anti-reflection layer. The buffer layer is formed on the copper-based compound semiconductor structure layer. The transparent conductive oxide layer is formed on the buffer layer. The second electrode layer is formed over the transparent conductive oxide layer. The anti-reflection layer is formed over the second electrode layer.

In an embodiment, the bifacial semiconductor structure further includes a first insulating layer and an isolation structure. The first insulating layer is formed on the first electrode layer. The copper-based compound semiconductor structure layer is formed over a part of first electrode layer and the first insulating layer. The isolation structure is formed on the first electrode layer. By the isolation structure, the copper-based compound semiconductor structure layer is divided into a third semiconductor structure and a fourth semiconductor structure.

In an embodiment, the bifacial semiconductor structure further includes a buffer layer, a transparent conductive oxide layer, a third electrode layer, an anti-reflection layer, a gate insulating layer, a source/drain metal electrode layer, and a metal gate layer. The buffer layer is formed on the third semiconductor structure. The transparent conductive oxide layer is formed on the buffer layer. The third electrode layer is formed over the transparent conductive oxide layer. The anti-reflection layer is formed over the third electrode layer. The gate insulating layer is formed on the fourth semiconductor structure. The source/drain metal electrode layer is formed on the fourth semiconductor structure. The metal gate layer is formed on the gate insulating layer.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic cross-sectional view illustrating a conventional bifacial semiconductor structure;

FIGS. 2A˜2E are a schematic cross-sectional views illustrating a partial process flow of fabricating a bifacial semiconductor structure according to an embodiment of the present invention; and

FIGS. 3A˜3E are a schematic cross-sectional views illustrating a partial process flow of fabricating a bifacial semiconductor structure according to another embodiment of the present invention.

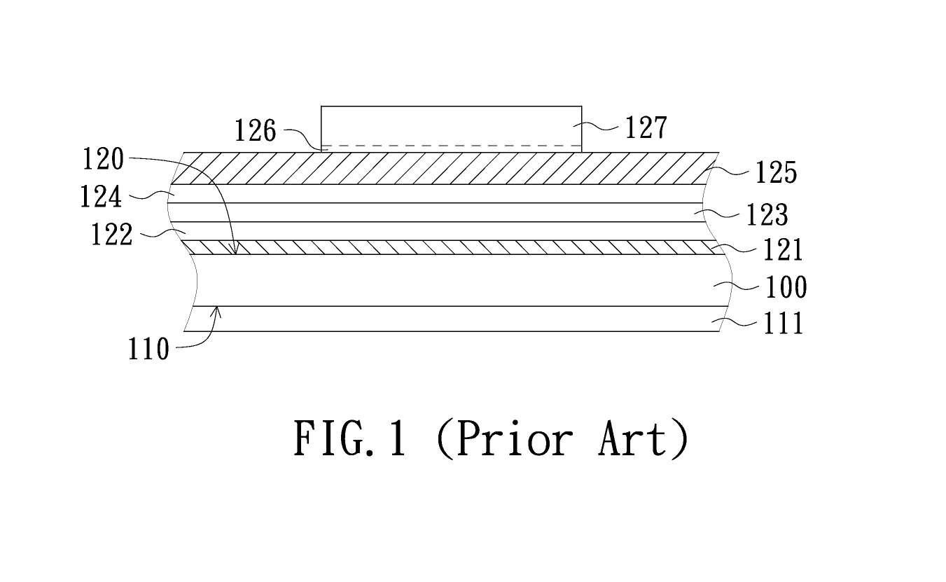

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

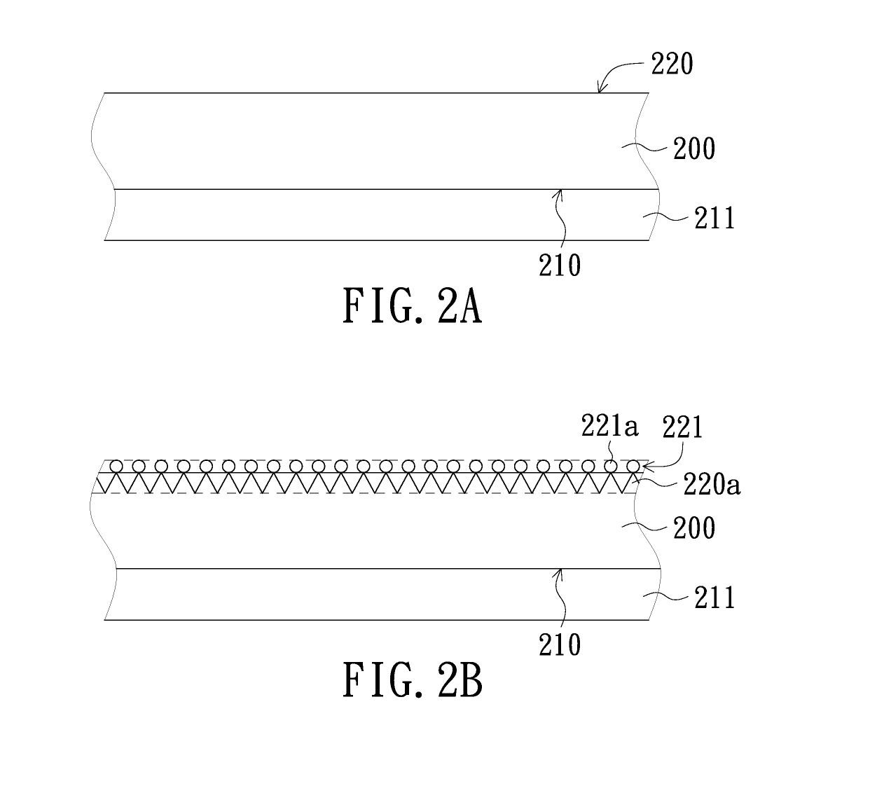

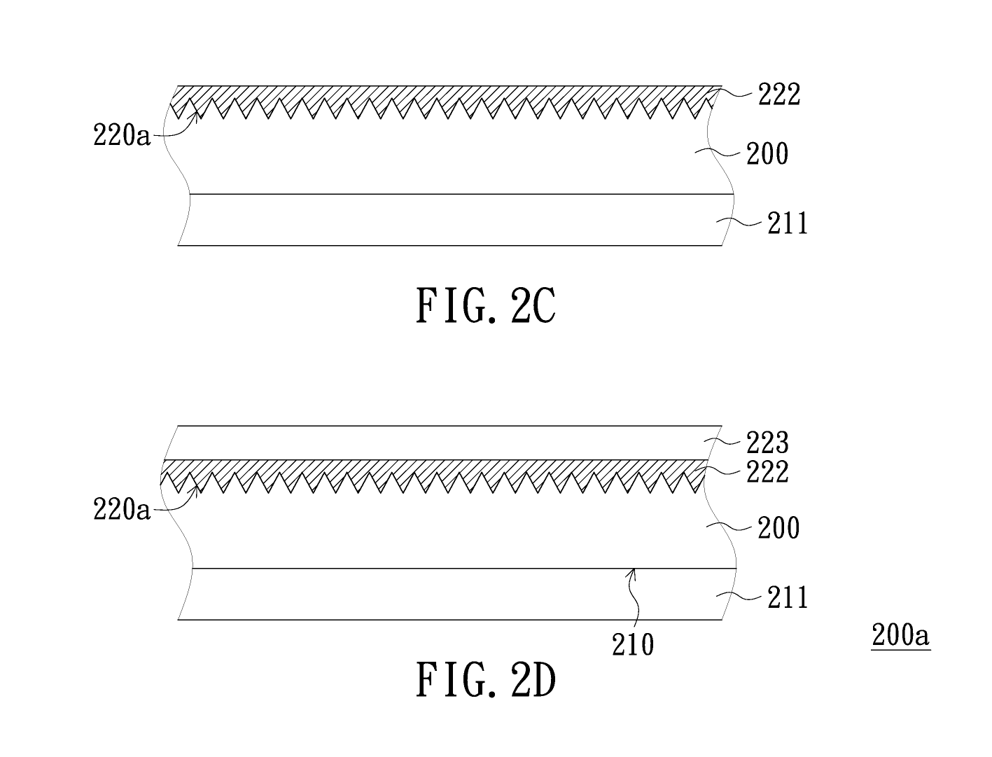

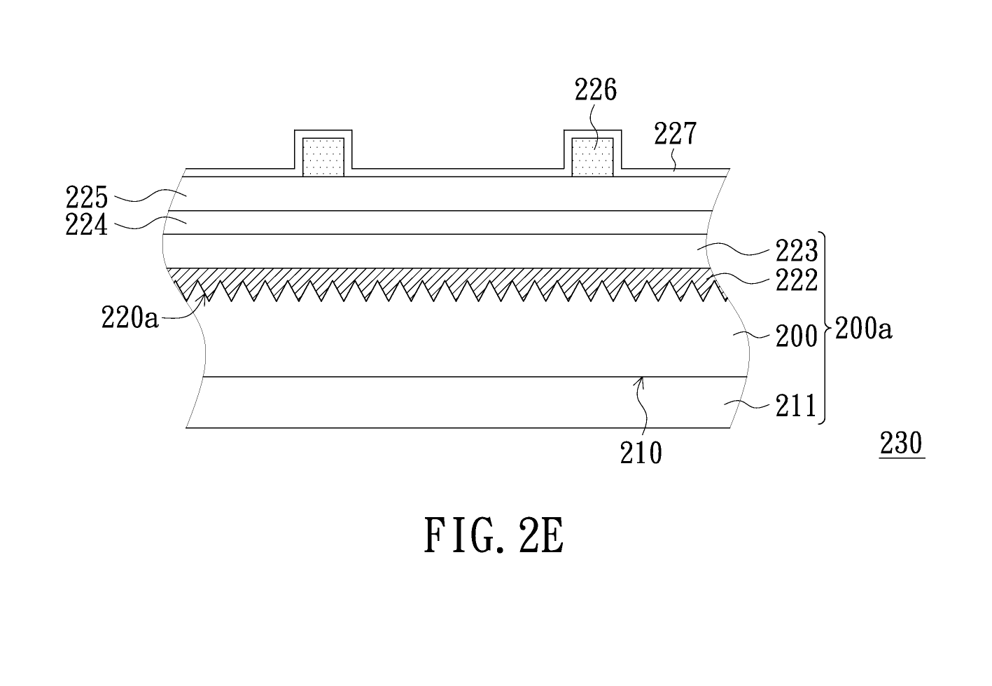

FIGS. 2A˜2E are a schematic cross-sectional views illustrating a partial process flow of fabricating a bifacial semiconductor structure according to an embodiment of the present invention.

Firstly, as shown in FIG. 2A, a silicon substrate 200 is provided. The silicon substrate 200 has a first surface 210 and a second surface 220. A first semiconductor structure 211 is formed on the first surface 210 of the silicon substrate 200. For example, the first semiconductor structure 211 is a functional circuit of a silicon semiconductor device (e.g. a silicon solar cell or a silicon transistor). In this embodiment, the first semiconductor structure 211 is illustrated by referring to the silicon solar cell.

Then, as shown in FIG. 2B, the second surface 220 of the silicon substrate 200 is textured by a chemical texturing process or a plasma etching process. The chemical texturing process is a chemical reaction between a mixture of potassium hydroxide, isopropanol and water and silicon. In this embodiment, the second surface 220 of the silicon substrate 200 is textured by the plasma etching process. The plasma etching process comprises the following steps. Firstly, a metal layer 221, which is indicated by dashed lines, is deposited on the second surface 220 of the silicon substrate 200. The metal layer 221 is for example a gold (Au) layer having 1˜30 nm thickness. Then, the metal layer 221 is annealed at 30˜500° C. to produce a plurality of Au nanoballs 221a. Then, by using the Au nanoballs 221a as a hard mask, the second surface 220 is etched under C4F8 or SF6 plasma gas by a plasma etching process. After the plasma etching process is performed, the Au nanoballs 221a are removed. Consequently, the second surface 220 is textured as a rough surface 220a. The rough surface 220a consists of numerous recesses. The depth of each recess is about 0.5˜1.5 μm, and the width of each recess is about 0.5˜1.5 μm.

Then, as shown in FIG. 2C, a first electrode layer 222 is formed on the rough surface 220a. In this embodiment, the first electrode layer 222 is a Mo layer having a deposition thickness of about 1.2 μm.

Then, as shown in FIG. 2D, a copper-based compound semiconductor structure layer 223 is formed over the first electrode layer 222. Meanwhile, the bifacial semiconductor structure 200a is fabricated. In this embodiment, the copper-based compound semiconductor structure layer 223 is produced by the following steps. Firstly, three elements copper (Cu), gallium (Ga) and selenide (Se) are deposited on the first electrode layer 222 by a co-evaporation process or a sputtering process to form a copper-gallium-selenide crystal seed layer having a thickness of about 0.2˜20 nm. Then, the copper-based compound semiconductor structure layer 223 is formed on the copper-gallium-selenide crystal seed layer by a co-evaporation process or a sputtering process.

In this embodiment, a three-stage co-evaporation process is performed to deposit four elements copper (Cu), indium (In), gallium (Ga) and selenide (Se) on the first electrode layer 222 in order to fabricate the copper-based compound semiconductor structure layer 223, i.e. the copper-indium-gallium-selenide (CIGS) compound semiconductor structure layer.

An exemplary three-stage co-evaporation process will be illustrated as follows.

In the first stage, the silicon substrate is heated to 400° C., and the Se deposition rate is maintained 40A/sec in order to grow a (InGa)ₓSe_{y} compound. Before the (InGa)ₓSe_{y} evaporation, the Cu and Ga shutters are opened, and a thin layer of CuGaSe₂ having a thickness of about 50 nm is formed on the Mo layer. The CuGaSe₂ layer is used to increase the CIGS adhesion and enhance the Ga content. After the 50 nm-thick CuGaSe₂ is formed, the In and Ga shutters are opened. The In and Ca deposition rates are about 4.7 Å/sec and 3 Å/sec, respectively, and the deposition time is 660 seconds. After the 660 seconds, the In and Ca deposition rates start to decline. The decline rate of In and Ga is 0.026 Å/sec and 0.02 Å/min, respectively. After 180 seconds, the In and Ga shutters are closed. Meanwhile, the first stage is ended.

In the second stage, a CuₓSe_{y} compound is grown. The Cu shutter is opened, and the Se deposition rate is also maintained at 40 Å/sec. The Cu deposition rate starts to increase from 0.023 Å/sec. After 150 seconds, the Cu deposition rate reaches 3.5 Å/sec, and this Cu deposition rate is maintained for 480 seconds. Moreover, after the second stage has started for 180 seconds, the temperature of the silicon substrate is increased to about 550° C. to generate an interaction reaction. The interaction reaction forms a CIGS film, and the excess CuSe is helpful to grow the crystal. After 480 seconds, the Cu deposition rate starts to decline. The decline rate of Cu is 0.025 Å/sec. After 180 seconds, the Cu shutter is closed.

In the third stage, the (InGa)ₓSe_{y} compound is grown again. The In and Ga shutters are opened, and the Se deposition rate is maintained 40 Å/sec. The initial In and Ca deposition rates are about 0.016 Å/sec and 0.008 Å/sec, respectively, and gradually increased. At the 180-th seconds, the In and Ca deposition rates are 3 Å/sec and 1.5 Å/sec, respectively, which are maintained for 180 seconds. Then, the In shutter is closed. After 10 seconds, the Ga shutter is closed. After the third stage, the Cu fraction is reduced in order to avoid Cu₂Se formation.

In some embodiments, the above three-stage co-evaporation process may be replaced by a three-stage sputtering process in order to form the copper-indium-gallium-selenide (CIGS) compound semiconductor structure layer.

It is noted that the rough surface 220a is effective to release the mechanical stress from the first electrode layer 222. As a consequence, the adhesion between the first electrode layer 222, the copper-based compound semiconductor structure layer 223 and the silicon substrate 200 is enhanced, and the possibility of delaminating the first electrode layer 222 and the copper-based compound semiconductor structure layer 223 is largely reduced.

Please refer to FIG. 2D again. The bifacial semiconductor structure 200a comprises the silicon substrate 200, the first semiconductor structure 211, the first electrode layer 222, and the copper-based compound semiconductor structure layer 223. The silicon substrate 200 has the first surface 210 and the rough surface 220a. The first semiconductor structure 211 is formed on the first surface 210 of the silicon substrate 200. The first electrode layer 222 is formed on the rough surface 220a of the silicon substrate 200. The copper-based compound semiconductor structure layer 223 is formed over the first electrode layer 222. In this embodiment, the first semiconductor structure 211 is a silicon solar cell, the first electrode layer 222 is a Mo layer, and the copper-based compound semiconductor structure layer 223 is a CIGS compound semiconductor structure layer.

Then, as shown in FIG. 2E, a buffer layer 224 is formed on the copper-based compound semiconductor structure layer 223, a transparent conductive oxide (TCO) layer 225 is formed over the buffer layer 224, a second electrode layer 226 is formed on the transparent conductive oxide layer 225, and an anti-reflection layer 227 is formed over the second electrode layer 226. Meanwhile, a copper-based compound semiconductor solar cell module 230 is fabricated. In this embodiment, the buffer layer 224 is a zinc sulfide (ZnS) layer formed by a chemical bath deposition process. The transparent conductive oxide layer 225 is an aluminum-doped zinc oxide (AZO) layer formed by deposition. For forming the second electrode layer 226, an aluminum layer is firstly formed on the transparent conductive oxide layer 225, and then the aluminum layer is partially removed. The remaining aluminum layer is acted as the second electrode layer 226. The anti-reflection layer 227 is a magnesium fluoride (MgF₂) layer formed by deposition. Optionally, a receptor-type semiconductor (p-type) structure layer and a donor-type semiconductor (n-type) structure layer are arranged between the TCO layer 225 and the second electrode layer 226 in order to absorb solar energy at different wavelength spectra. For example, the receptor-type semiconductor structure layer and the donor-type semiconductor are a p-type silicon layer and an n-type silicon layer, respectively. Alternatively, the receptor-type semiconductor structure layer and the donor-type semiconductor are another p-type copper-based compound semiconductor structure layer and an n-type buffer layer.

Please refer to FIG. 2E again. In addition to the bifacial semiconductor structure 200a, the copper-based compound semiconductor solar cell module 230 further comprises the buffer layer 224, the transparent conductive oxide layer 225, the second electrode layer 226, and the anti-reflection layer 227. The buffer layer 224 is formed on the copper-based compound semiconductor structure layer 223. The transparent conductive oxide layer 225 is formed on the buffer layer 224. The second electrode layer 226 is formed over the transparent conductive oxide layer 225. The anti-reflection layer 227 is formed over the second electrode layer 226.

From the above description, the bifacial semiconductor structure and the fabricating method thereof can be applied to the fabrication of a copper-based compound semiconductor solar cell. It was found that the rough surface 220a of the silicon substrate 200 can reduce the optical reflection but increase the optical absorption of the solar cell. Due to enhanced light trapping and reduced reflection, the copper-based compound semiconductor structure layer 223 exhibit higher external quantum efficiency in the spectrum range of 380˜1100 nm. Consequently, the short-circuit current density and the photovoltaic conversion efficiency of the copper-based compound semiconductor solar cell module 230 are both enhanced. Moreover, the silicon solar cell 211 and the copper-based compound semiconductor solar cell module 230 are integrated as a bifacial solar cell. The first electrode layer 222 may be used as a common electrode of the bifacial solar cell. After the silicon solar cell 211 or the copper-based compound semiconductor solar cell module 230 receives the external light to generate carrier current, the carrier current can be transmitted through the first electrode layer 222, so that the associated electronic component can be electrically connected with each other.

In other words, the applications of the bifacial solar cell are expanded.

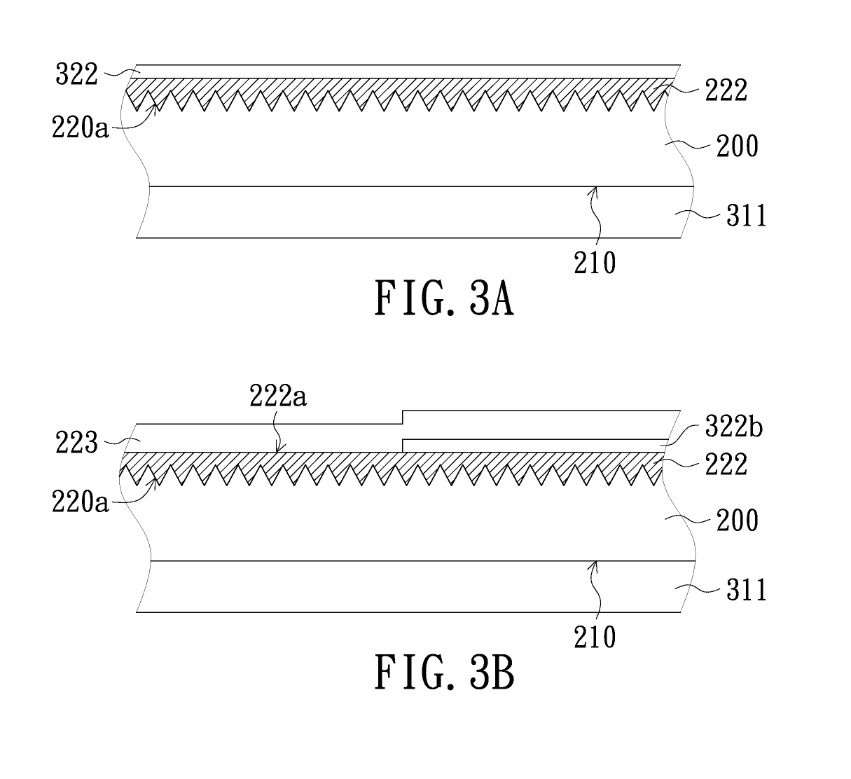

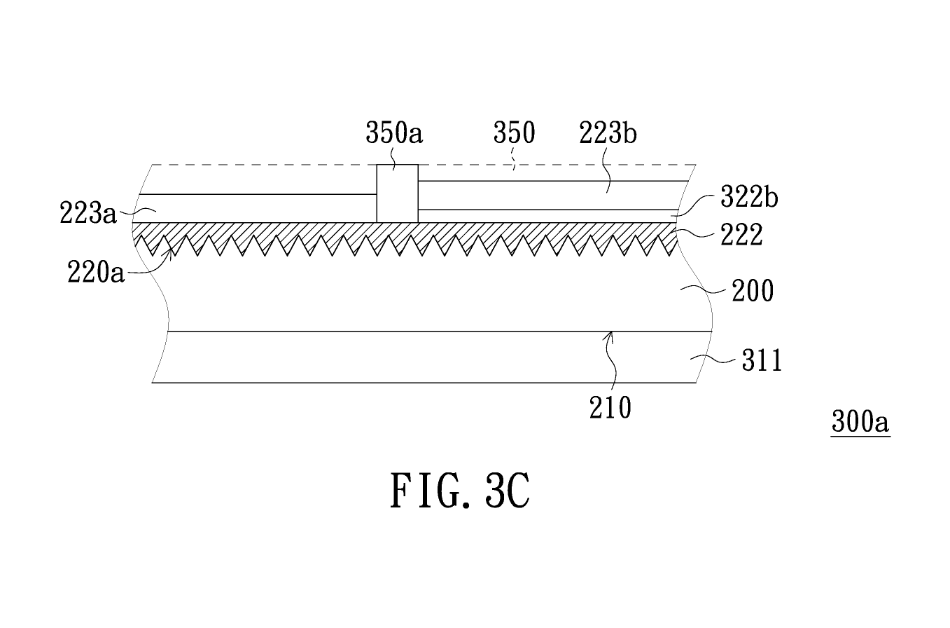

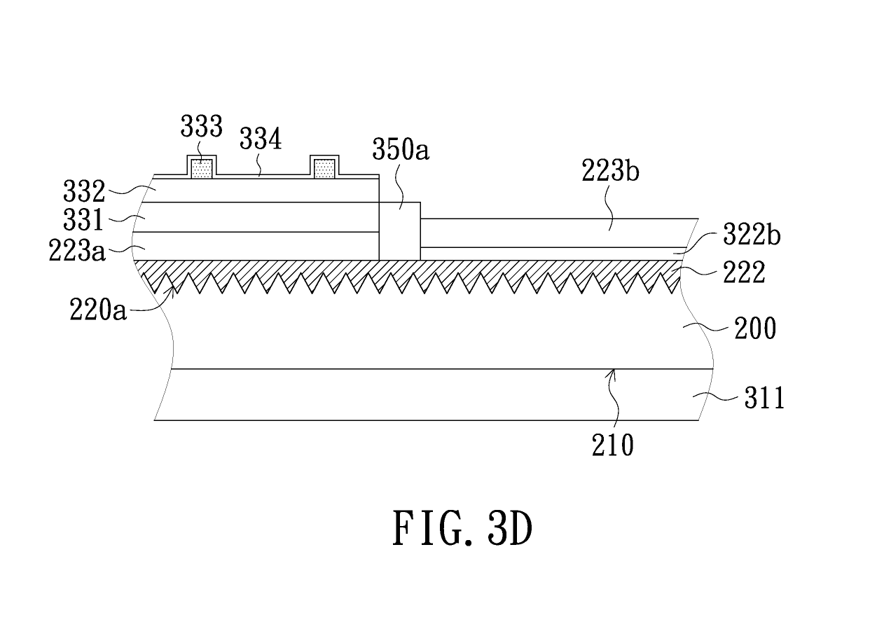

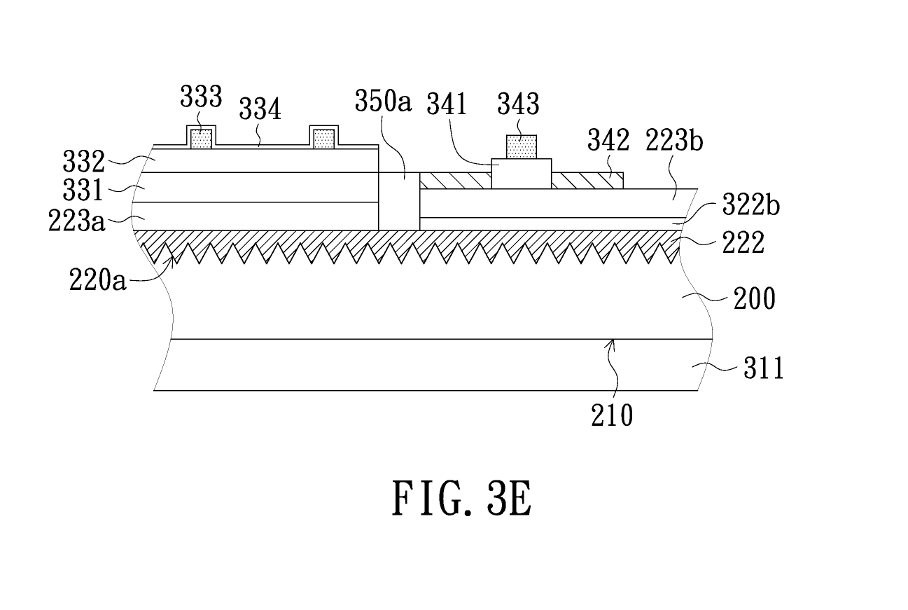

FIGS. 3A˜3E are a schematic cross-sectional views illustrating a partial process flow of fabricating a bifacial semiconductor structure according to another embodiment of the present invention.

Firstly, as shown in FIG. 3A, a silicon substrate 200 is provided. The silicon substrate 200 has a first surface 210 and a rough surface 220a. A first semiconductor structure 311 is formed on the first surface 210 of the silicon substrate 200. For example, the first semiconductor structure 311 is a silicon semiconductor device (e.g. a silicon solar cell or a silicon transistor). In addition, a first electrode layer 222 is formed on the rough surface 220a, and a first insulating layer 322 is formed on the first electrode layer 222. In this embodiment, the first insulating layer 322 is formed by depositing a silicon dioxide layer.

Then, as shown in FIG. 3B, the first insulating layer 322 is partially removed to expose a part of the first electrode layer 222. Then, the exposed part 222a of the first electrode layer 222 and the remaining first insulating layer 322b are covered by a copper-based compound semiconductor structure layer 223.

Then, as shown in FIG. 3C, the copper-based compound semiconductor structure layer 223 is partially removed to expose a part of the first electrode layer 222. Then, an isolation structure 350a is formed on the exposed part of the first electrode layer 222. By the isolation structure 350a, the remaining copper-based compound semiconductor structure layer 223 is divided into a third semiconductor structure 223a and a fourth semiconductor structure 223b. Meanwhile, the bifacial semiconductor structure 300a is fabricated. Please refer to FIG. 3C again. A way of forming the isolation structure 350a will be illustrated as follows. After the copper-based compound semiconductor structure layer 223 is partially removed to expose the part of the first electrode layer 222, the remaining copper-based compound semiconductor structure layer 223 and the exposed part of the first electrode layer 22 are covered by a silicon dioxide layer 350, which is indicated by the dashed line. Then, the silicon dioxide layer 350 is partially removed to expose the remaining copper-based compound semiconductor structure layer 223, and thus the remaining part of the silicon dioxide layer 350 is acted as the isolation structure 350a.

Please refer to FIG. 3C again. In comparison to the bifacial semiconductor structure 200a as shown in FIG. 2D, the bifacial semiconductor structure 300a further comprises the first insulating layer 322b and the isolation structure 350a. The first insulating layer 322b is formed on the first electrode layer 222. In addition, the copper-based compound semiconductor structure layer 223 is formed on a part of the first electrode layer 222 and the first insulating layer 322b. The isolation structure 350a is formed on the first electrode layer 222. By the isolation structure 350a, the copper-based compound semiconductor structure layer 223 is divided into the third semiconductor structure 223a and the fourth semiconductor structure 223b.

Then, as shown in FIG. 3D, a buffer layer 331 is formed on the third semiconductor structure 223a, a transparent conductive oxide layer 332 is formed over the buffer layer 331, a third electrode layer 333 is formed on the transparent conductive oxide layer 332, and an anti-reflection layer 334 is formed over the third electrode layer 333. Meanwhile, a copper-based compound semiconductor solar cell module is fabricated. In this embodiment, the buffer layer 331 is a donor-type semiconductor layer (e.g. a zinc sulfide layer) formed by a chemical bath deposition process. The transparent conductive oxide layer 332 is an aluminum-doped zinc oxide (AZO) layer formed by deposition. The third electrode layer 333 is an aluminum layer. The anti-reflection layer 334 is a magnesium fluoride (MgF₂) layer formed by deposition.

Then, as shown in FIG. 3E, a gate insulating layer 341 is formed on the fourth semiconductor structure 223b. Then, the gate insulating layer 341 is partially removed to expose a part of the fourth semiconductor structure 223b. Then, a source/drain metal electrode layer 342 is formed on the exposed part of the fourth semiconductor structure 223b. Then, a metal gate layer 343 is formed on the remaining gate insulating layer 341. Meanwhile, a copper-based compound semiconductor thin film transistor is fabricated. In this embodiment, the gate insulating layer 341 is an aluminum oxide (Al₂O₃) layer, the source/drain metal electrode layer 342 is a platinum (Pt) layer, and the metal gate layer 343 is an aluminum layer. Moreover, copper-based compound semiconductor solar cell module and the copper-based compound semiconductor thin film transistor may be integrated as a self-powered module.

Please refer to FIG. 3E again. In addition to the bifacial semiconductor structure 300a as shown in FIG. 3C, the resulting structure of FIG. 3E further comprises the buffer layer 331, the transparent conductive oxide layer 332, the third electrode layer 333, the anti-reflection layer 334, the gate insulating layer 341, the source/drain metal electrode layer 342, and the metal gate layer 343. The buffer layer 331 is formed on the third semiconductor structure 223a. The transparent conductive oxide layer 332 is formed on the buffer layer 331. The third electrode layer 333 is formed over the transparent conductive oxide layer 332. The anti-reflection layer 334 is formed over the third electrode layer 333. The gate insulating layer 341 is formed on the fourth semiconductor structure 223b. The source/drain metal electrode layer is formed on the fourth semiconductor structure 223b. The metal gate layer 343 is formed on the remaining gate insulating layer 341.

From the above description, the fabricating method of the bifacial semiconductor structure is compatible with the silicon semiconductor fabricating process. By the fabricating method of the present invention, it is not necessary to form a plurality of nitride or oxide insulating layers on the silicon substrate and it is not necessary to diffuse sodium elements into the copper-based compound semiconductor structure to increase the photovoltaic conversion efficiency. Since the common electrode and the copper-based compound semiconductor structure layer of the bifacial semiconductor structure are formed on the rough surface at a temperature lower than 550° C., the fabricating cost is largely reduced, and the first semiconductor structure may be integrated into the first surface of the silicon substrate. Under this circumstance, the applications of the bifacial semiconductor structure are expanded. For example, the bifacial semiconductor structure of the present invention may be applied to a bifacial solar cell or a self-powered module. In addition, the bifacial semiconductor structure of the present invention may be applied to sensors, electronic paper, ID tags or building integrated photovoltaic (BIPV) applications in order to achieve the environmental protection and power-saving purposes.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor structure fabricating method for fabrication of a bifacial semiconductor device, the semiconductor structure fabricating method comprising steps of:
providing a silicon substrate, wherein the silicon substrate has a first surface and a second surface, and a first semiconductor structure is formed on the first surface of the silicon substrate;
texturing the second surface of the silicon substrate as a rough surface; and
forming a first electrode layer on the rough surface.

2. The semiconductor structure fabricating method according to claim 1, wherein the step of texturing the second surface of the silicon substrate as the rough surface comprises sub-steps of:
forming a metal layer on the second surface of the silicon substrate;
annealing the metal layer to form a plurality of metal nanoballs;
performing a plasma etching process to texture the second surface of the silicon substrate by using the metal nanoballs as a hard mask, so that the second surface of the silicon substrate is textured as the rough surface; and
removing the metal nanoballs after the plasma etching process is performed.

3. The semiconductor structure fabricating method according to claim 2, wherein the metal layer is a gold (Au) layer having 1˜30 nm thickness.

4. The semiconductor structure fabricating method according to claim 1, wherein the first electrode layer is formed by depositing a molybdenum (Mo) layer.

5. The semiconductor structure fabricating method according to claim 1, further comprises a step of forming a copper-based compound semiconductor structure layer to cover the first electrode layer.

6. The semiconductor structure fabricating method according to claim 5, wherein the step of forming the copper-based compound semiconductor structure layer comprises sub-steps of:
forming a crystal seed layer having about 0.2˜20 nm thickness over the first electrode layer by a co-evaporation process or a sputtering process, wherein the crystal seed layer comprises copper, gallium and selenide atoms; and
forming the copper-based compound semiconductor structure layer on the crystal seed layer by a three-stage co-evaporation process or a three-stage sputtering process, so that the first electrode layer is covered by the copper-based compound semiconductor structure layer.

7. The semiconductor structure fabricating method according to claim 5, wherein the copper-based compound semiconductor structure layer is produced at a temperature lower than 550° C.

8. The semiconductor structure fabricating method according to claim 5, further comprising steps of:
forming a buffer layer on the copper-based compound semiconductor structure layer;
forming a transparent conductive oxide layer on the buffer layer;
forming a second electrode layer over the transparent conductive oxide layer; and
forming an anti-reflection layer over the second electrode layer.

9. The semiconductor structure fabricating method according to claim 8, wherein the buffer layer is an n-type semiconductor layer.

10. The semiconductor structure fabricating method according to claim 8, wherein the transparent conductive oxide layer is formed on the buffer layer by depositing a transparent conductive oxide material.

11. The semiconductor structure fabricating method according to claim 8, wherein the step of forming the second electrode layer comprises sub-steps of:
forming an aluminum layer on the transparent conductive oxide layer; and
partially removing the aluminum layer, wherein the remaining aluminum layer is acted as the second electrode layer.

12. The semiconductor structure fabricating method according to claim 8, wherein the anti-reflection layer is formed by depositing a magnesium fluoride (MgF₂) layer.

13. The semiconductor structure fabricating method according to claim 1, further comprising steps of:
forming a first insulating layer on the first electrode layer;
partially removing the first insulating layer to expose a part of the first electrode layer;
forming a copper-based compound semiconductor structure layer on the exposed part of the first electrode layer and the remaining first insulating layer;
partially removing the copper-based compound semiconductor structure layer to expose a part of the first electrode layer; and
forming an isolation structure on the exposed part of the first electrode layer, wherein by the isolation structure, the remaining copper-based compound semiconductor structure layer is divided into a third semiconductor structure and a fourth semiconductor structure.

14. The semiconductor structure fabricating method according to claim 13, wherein the first insulating layer is formed by depositing a silicon dioxide layer.

15. The semiconductor structure fabricating method according to claim 13, wherein the step of forming the isolation structure comprises sub-steps of:
depositing a silicon dioxide layer to cover the remaining copper-based compound semiconductor structure layer and the exposed part of the first electrode layer; and
partially removing the silicon dioxide layer to expose the remaining copper-based compound semiconductor structure layer, so that the remaining silicon dioxide layer is acted as the isolation structure.

16. The semiconductor structure fabricating method according to claim 13, further comprising steps of:
forming a buffer layer on the third semiconductor structure;
forming a transparent conductive oxide layer on the buffer layer;
forming a third electrode layer over the transparent conductive oxide layer;
forming an anti-reflection layer over the third electrode layer;
forming a gate insulating layer on the fourth semiconductor structure;
partially removing the gate insulating layer to expose a part of the fourth semiconductor structure;
forming a source/drain metal electrode layer on the exposed part of the fourth semiconductor structure; and
forming a metal gate layer on the remaining gate insulating layer.

17. A bifacial semiconductor structure, comprising:
a silicon substrate having a first surface and a rough surface, wherein a first semiconductor structure is formed on the first surface of the silicon substrate;
a first electrode layer formed on the rough surface; and
a copper-based compound semiconductor structure layer formed over the first electrode layer.

18. The bifacial semiconductor structure according to claim 17, further comprising:
a buffer layer formed on the copper-based compound semiconductor structure layer;
a transparent conductive oxide layer formed on the buffer layer;
a second electrode layer formed over the transparent conductive oxide layer; and
an anti-reflection layer formed over the second electrode layer.

19. The bifacial semiconductor structure according to claim 17, further comprising:
a first insulating layer formed on the first electrode layer, wherein the copper-based compound semiconductor structure layer is formed over a part of first electrode layer and the first insulating layer; and
an isolation structure formed on the first electrode layer, wherein by the isolation structure, the copper-based compound semiconductor structure layer is divided into a third semiconductor structure and a fourth semiconductor structure.

20. The bifacial semiconductor structure according to claim 19, further comprising:
a buffer layer formed on the third semiconductor structure;
a transparent conductive oxide layer formed on the buffer layer;
a third electrode layer formed over the transparent conductive oxide layer;
an anti-reflection layer formed over the third electrode layer;
a gate insulating layer formed on the fourth semiconductor structure;
a source/drain metal electrode layer formed on the fourth semiconductor structure; and
a metal gate layer formed on the gate insulating layer.
